(19) United States
(12) Patent Application Publication
(10) Pub. No.: US 2005/0263678 A1
(43) Pub. Date: Dec. 1, 2005

(54) Image processing apparatus

(75) Inventor: Kenji Arakawa, Kyoto-shi (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 11/137,573

(22) Filed: May 26, 2005

(30) Foreign Application Priority Data
May 26, 2004 (JP) P. 2004-156262

(51) Int. Cl. H01L 27/00

(52) U.S. Cl. 250/208.1

(57) ABSTRACT

An image processing apparatus 1 having: an imaging element A3 for converting light from an object 100 into an image signal A; an imaging element B4 larger than the imaging element A3 in the number of pixels for converting light from the object 100 into an image signal B; imaging devices A6 and B7 capable of driving the imaging elements A3 and B4 independently; an image processing section 5 for converting image signals A and B into image data A and B; an encoding device 19 for converting the image data A and B into code data A and B; and a central processing unit 15 for varying the compression rate in the encoding device 19 based on the code quantity of the code data A and controlling the encoding device so as to make the cod data B fixed in length.

### BACKGROUND OF THE INVENTION

1. Field of the Invention

The present invention relates to an image processing apparatus including imaging elements such as CCDs (Charge Coupled Devices) and CMOSs (Complementary Metal Oxide Semiconductors).

2. Description of the Related Art

FIG. 5 is a block diagram showing a schematic configuration of a conventional image processing apparatus 51. The conventional image processing apparatus 51 includes: an imaging element 54 for converting light from an object into image signals; an imaging optical system 59 in association with the imaging element 54; an imaging device 57 for driving the imaging element 54; an contour extracting device 67 for extracting the contour information of the object by a contrast detecting scheme out of the image signals supplied from the imaging device 57; an image processing section 55 for performing a process of converting image signals supplied from the imaging device 57 into image data; an encoding device 69 for converting image data supplied from the image processing section 55 into code data; and a central processing unit 65 for controlling the imaging optical system 59, imaging device 57, etc. and performing a process of producing a thumbnail based on image data.

Code data to be handled by the image processing apparatus 51, such as JPEG (Joint Photographic Experts Group), conform to DCF (design rule for Camera File system) standard, and have a reduced image, referred to as “thumbnail,” contained in its header portion. Also, the thumbnail is encoded like the code data of the body image thereof.

FIG. 6 is a view showing an image processing sequence that the conventional image processing apparatus 51 conducts. In the drawing are represented processing conditions in the operation blocks when the image processing apparatus 51 is changed in its mode from monitor-shooting to still (still picture) shooting. As shown in FIG. 6, the image processing section 55 carries out image processing in parallel with image signal output by the imaging element 54. While the encoding device 69 performs a process of encoding, the device usually conducts code quantity estimation to make the quantity of codes constant (i.e. to facilitate file management), too.

Based on a result of the code quantity estimation, the encoding device 69 carries out full compression with a compression rate set higher when the estimation is larger than a predeterminated code quantity or with the compression rate set lower when the estimation is smaller than the predeterminated quantity. Then, a main image is resized and scaled down from its primary size to a thumbnail size, followed by estimating the scale-down image data in code quantity as having estimated the main image. Based on the result of the estimation process, the full compression of the thumbnail is performed.

At the time when the full compression of the thumbnail has ended, all the data required for a JPEG file are given. There are cases where the code quantity estimation is not conducted for some products. However, in any case, thumbnail resizing and encoding are performed after the encoding of a main image.

Japanese Patent Application No. 2000-81545 (JP-A-2001-268437) is referred as the related art.

However, the conventional image processing apparatus has been under the following circumstance. That is, it takes a lot of time before a thumbnail is produced from an image data to form a JPEG file. During this process, “nothing is displayed” on a monitor, or a final monitor image is displayed and as such, it is impossible for a user to follow an object on the monitor.

### SUMMARY OF THE INVENTION

The invention was made in consideration of the foregoing circumstance. It is an object of the invention to provide an image processing apparatus capable of producing an image file at a higher speed.

The image processing apparatus of the invention is an image processing apparatus for producing an image file including first and second image data, having:

first and second imaging elements for converting light from an object into image signals; and

an image-converting section for converting image signals from the first and second imaging elements into the first and second image data respectively. According to the arrangement, first and second image data needed to produce an image file can be obtained based on image signals from the first and second imaging elements respectively and as such, the first and second image data, which have been sequentially produced based on a single kind of image signals in the past, can be produced substantially at a time. Therefore, it is possible to produce an image file at a higher speed.

Also, in the image processing apparatus of the invention, the first imaging element is smaller than the second imaging element in pixel number. The arrangement can reduce the cost because the number of pixels that the first imaging element has is smaller than that of the second imaging element.

Further, the image processing apparatus of the invention has an encoding device for combining the second image data encoded with a compression rate based on a code quantity of the first image data and the encoded first image data thereby to produce the image file. According to the arrangement, the image file is produced by combining the second image data encoded with a compression rate based on a code quantity of the first image data and the encoded first image data and as such, the code quantity of the second image data doesn't have to be estimated. Therefore, an encoded image file can be produced at a higher speed.

Still further, in the image processing apparatus of the invention, the encoding device makes the first and second image data fixed in length. According to the arrangement, the first and second image data are made fixed in length by the encoding device and as such, the management of image files can be facilitated.

Furthermore, in the image processing apparatus of the invention, the encoding device combines the encoded first image data as a thumbnail with the encoded second image data. According to the arrangement, the encoding device combines the encoded first image data as a thumbnail with the encoded second image data, thereby making it possible to create an image file with the thumbnail at a higher speed.

According to the image processing apparatus of the invention, first and second image data needed to produce an image file can be obtained based on image signals from the first and second imaging elements respectively and as such, the first and second image data, which have been sequentially produced based on a single kind of image signals in the past, can be produced substantially at a time. Therefore, it is possible to produce an image file at a higher speed.

### BRIEF DESCRIPTION OF THE DRAWINGS

FIG. 1 is a block diagram of assistance in explaining an embodiment of the invention, which shows a schematic configuration of an image processing apparatus 1.

FIG. 2 is a block diagram showing a schematic configuration of the image processing apparatus 1 with a display device 13 and recording device 20 added therein.

FIG. 3 is a view showing the operation timing of the image processing apparatus 1.

FIG. 4 is a sequence diagram showing a series of processes performed until the image processing apparatus 1 completes a JPEG file.

FIG. 5 is a block diagram showing a schematic configuration of a conventional image processing apparatus 51.

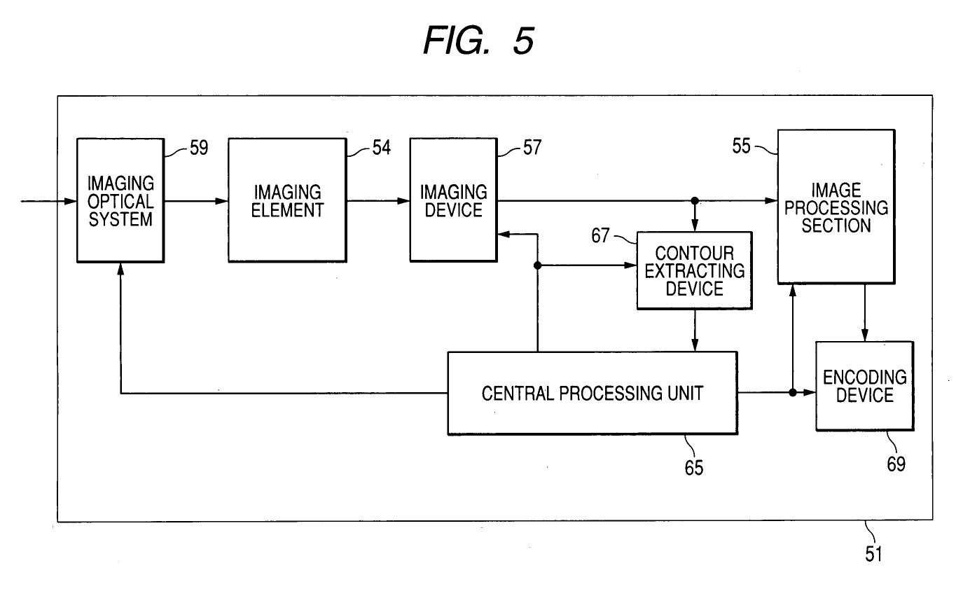

FIG. 6 is a view showing an image processing sequence that the conventional image processing apparatus 51 conducts.

### DESCRIPTION OF THE PREFERRED EMBODIMENTS

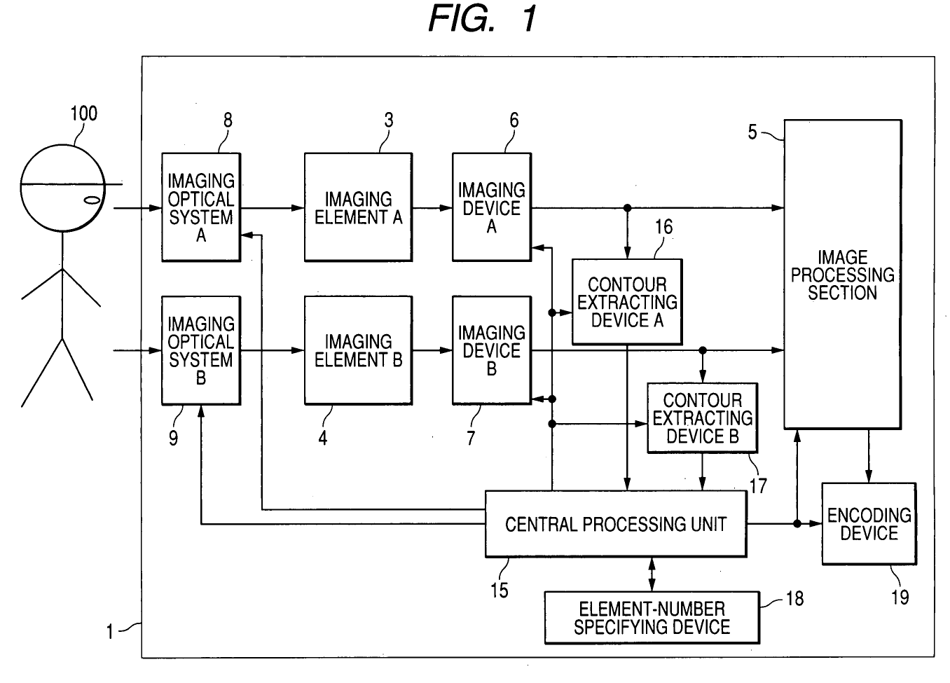

FIG. 1 is a block diagram of assistance in explaining an embodiment of the invention, which shows a schematic configuration of the image processing apparatus 1. As shown in FIG. 1, the image processing apparatus 1 is intended to produce an image file including an image data A and an image data B, and has: an imaging element A3 for converting light from an object 100 into an image signal A; an imaging element B4 for converting light from the object 100 into an image signal B, which is larger than the imaging element A3 in pixel number; imaging devices A6 and B7 for driving the imaging elements A3, B4 independently; an image processing section 5 for converting image signals A and B into image data A and B respectively; an encoding device 19 for combining an image data B encoded with a compression rate based on the code quantity of the image data A and the encoded image data A thereby to produce an image file; and a central processing unit 15 for varying the compression rate in the encoding device 19 based on the code quantity of the code data A and controlling the encoding device 19 so as to make the code data B fixed in length.

Also, the image processing apparatus 1 has: imaging optical systems A8 and B9 respectively corresponding to the imaging elements A3 and B4, which are identical with or different from each other in focal distance; contour extracting devices A16 and B17 which use image signals A and B to extract the contour information of the object 100 by the contrast detecting scheme; and an element-number specifying device 18 for specifying the number of imaging elements A3 and B4 to be caused to focus.

In the image processing apparatus 1, the imaging elements A3 and B4 are independently driven by the imaging devices A6 and B7 and as such, staggering the times to start driving the imaging elements A3 and B4 allows high speed successive shooting to be performed.

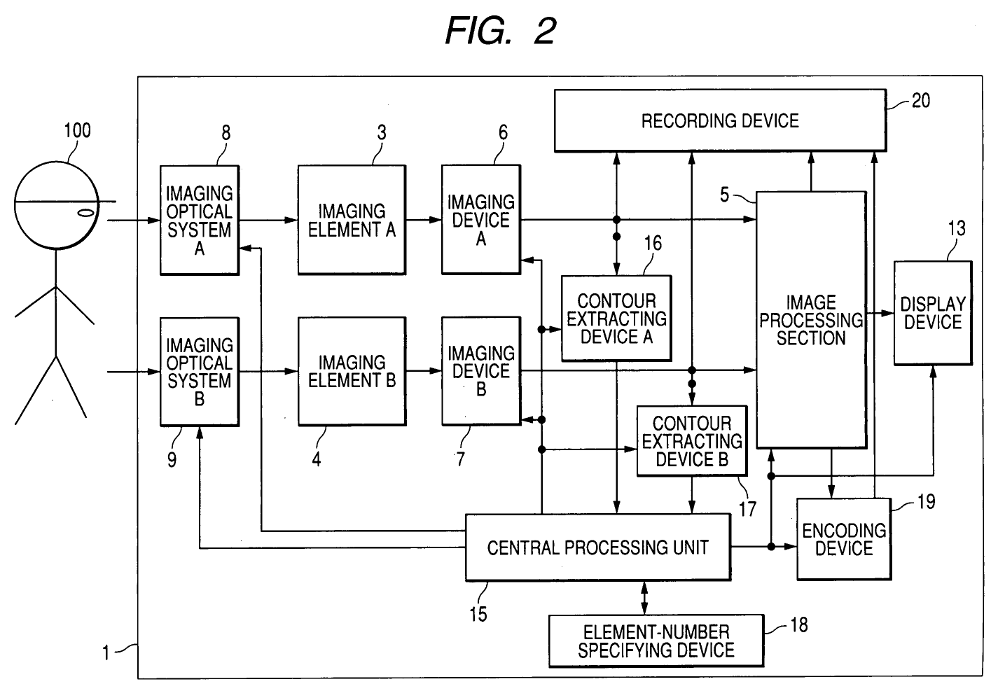

FIG. 2 is a block diagram showing a schematic configuration of the image processing apparatus 1 with a display device 13 and recording device 20 added therein. As shown in FIG. 2, the image processing apparatus 1 has a display device 13 for displaying an image data output from the image processing section 5 and a recording device 20 for recording at least one of the sets of image signals A and B, image data A and B, and code data A and B, in addition to the configuration shown in FIG. 1.

The image processing apparatus 1 can reduce the data amount of an image data because it has the encoding device 19 for encoding an image data produced in the image processing section 5 by JPEG method thereby to produce a code data. Also, the image processing apparatus 1 can record an image signal A obtained by the imaging element A3, an image data A and a code data A, an image signal B obtained by the imaging element B4, and an image data B and a code data B because it has the recording device 20 capable of recording a code data produced in the encoding device 19, image signals output from the imaging devices A6 and B7, and an image data output from the image processing section 5.

Now, the process of encoding performed by the encoding device 19 will be described. For example, in the case where the imaging element A3 is of 300,000 pixels and the imaging element B4 is of 9,000,000 pixels, when an image data B is to be converted into a code data B in the encoding device 19, an image data A resulting from conversion of an image signal from the imaging element A3 having a smaller number of pixels is first encoded. Then, based on the code quantity of the resulting code data A, the central processing unit 15 sets a compression rate used in encoding the image data B in the encoding device 19. In this case, the number of pixels of the imaging element B4 is 30 times as much as that of the imaging element A3 and as such, the code data B becomes 30 times or more as large as the code data A in code amount. Here, the reason why the code data B becomes 30 times or more in code amount is the imaging element A3 can not record high frequency components (i.e. high contrast components) in comparison to the imaging element B4 because of its small number of pixels and as such, it is expected that when a code data B is produced with the same compression rate, the code quantity thereof is 30 times larger than that of the code data A.

By setting the compression rate of an image data B based on the code quantity of a code data A to make the code quantity of the code data B fixed in length in this way, it makes possible to perform the fixed-length encoding at a higher speed in comparison to the case where the code quantity of an image data B is estimated before the image data B is encoded and made fixed in length as a conventional manner.

Also, an image data obtained by shooting during monitoring through the imaging device A3 can be confirmed with the display device 13 when the image processing section 5 outputs the image data A to the display device 13. This allows the imaging element A3 used in monitor-shooting to be reduced in the number of pixels. Therefore, it can be expected to reduce the cost for the imaging element A3, and the power consumption in monitor-shooting can be cut down.

The image processing apparatus 1 of the embodiment converts an image signal A output from the imaging element A3 having a smaller number of pixels into an image data A, converts an image signal B output from the imaging element B4 having a larger number of pixels into an image data B, combines a code data A resulting from the encoding of the image data A as a thumbnail with a code data B resulting from the encoding of the image data B, and then produces a code file. This makes it possible to omit to time and effort to resize an image data B and then produce a thumbnail, thereby facilitating file creation.

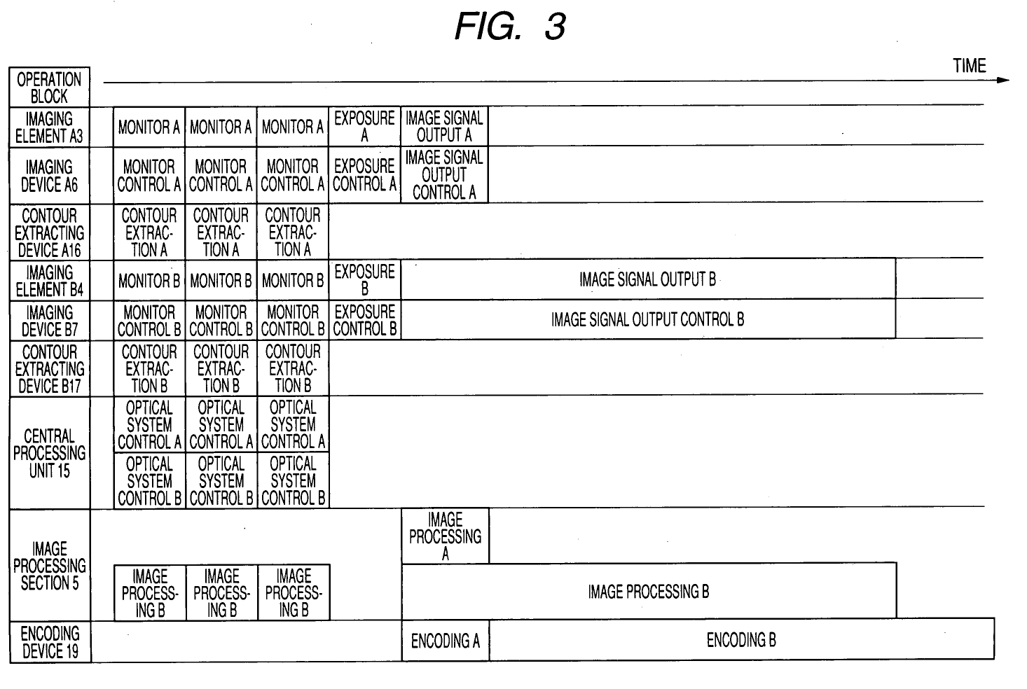

FIG. 3 is a view showing the operation timing of the image processing apparatus 1. Here is shown an example in which the imaging element A3 has 160 pixels horizontally and 120 pixels vertically, and the imaging element B4 is of 4,000,000 pixels. As shown in FIG. 3, the imaging element A3 is smaller than the imaging element B4 in the number of pixels and as such, image signal output A by the imaging element A3 ends in a short time. An image data A resulting from the conversion of the image signal A is encoded in the encoding device 19. A code data A resulting from the encoding can be used as a thumbnail. It is clear from FIG. 3 that a thumbnail (i.e. code data A) can be produced by the time when the image signal output B ends.

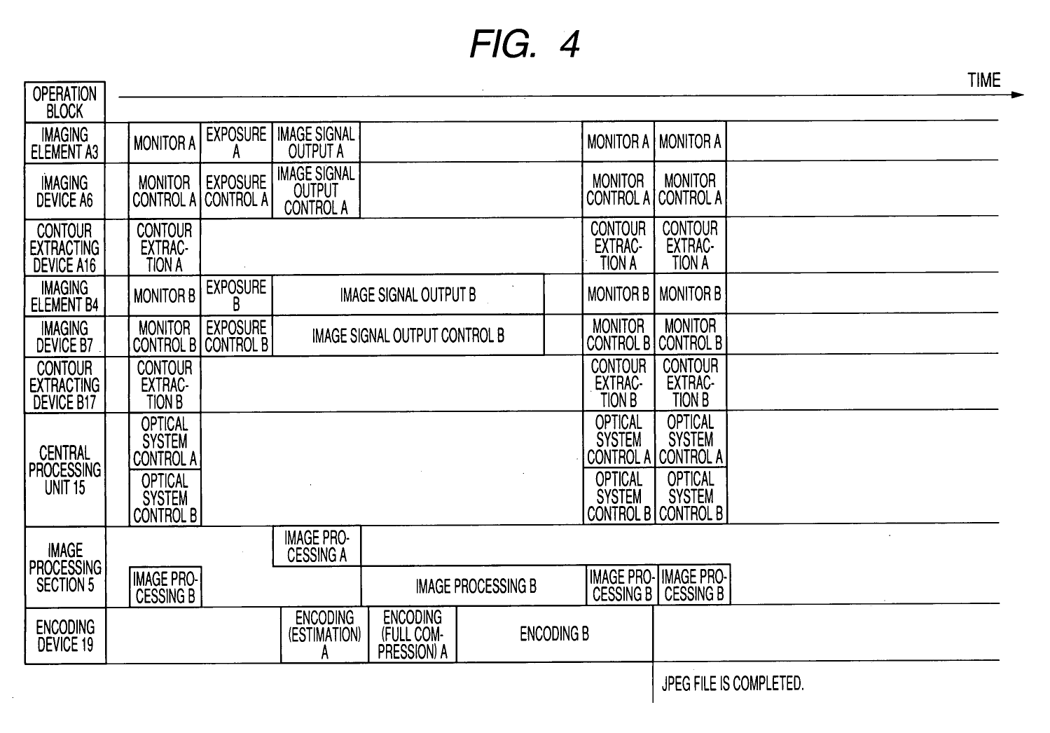

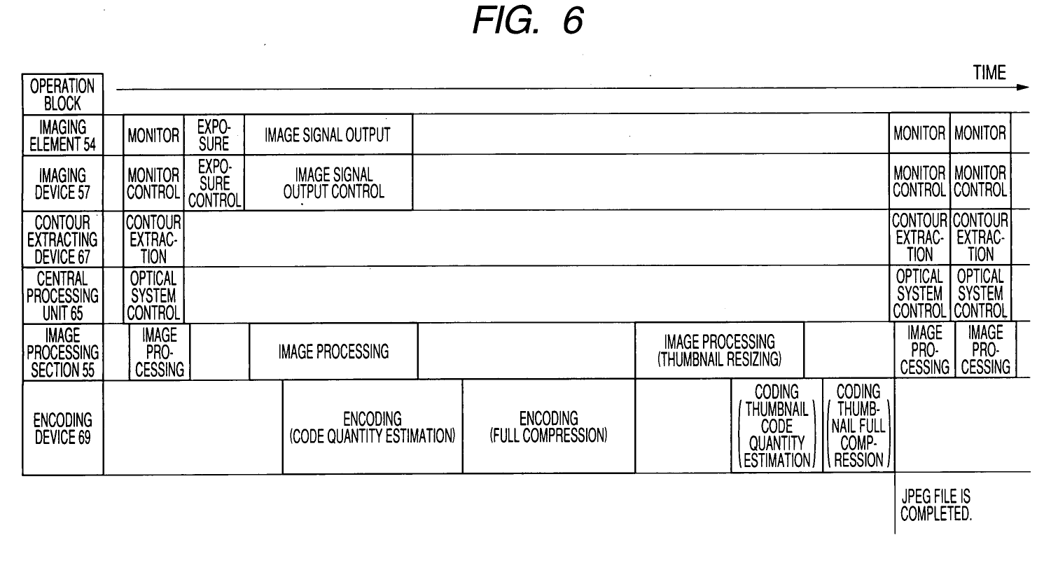

FIG. 4 is a sequence diagram showing a series of processes performed until the image processing apparatus 1 completes a JPEG file. The imaging element A3 has the a number of pixels intended for a thumbnail-sized image and the imaging element B4 has a number of pixels which enable an image having an image size for a main image to be taken. As shown in FIG. 4, because the number of pixels of the imaging element A3 for a thumbnail is small, the time required for image signal output is made shorter. Then, according to the result of the process of code quantity estimation for a thumbnail, full compression for a thumbnail is carried out. Compression of a main image using the compression rate for a thumbnail eliminates the need for carrying out the code quantity estimation of the main image. Therefore, the time that elapses before a JPEG file is completed can be made shorter in comparison to the case of one imaging element 54 as shown in FIG. 6.

The invention is not limited to the above embodiment, and it may be embodied as follows.

(1) While in the above description, a case where the imaging element A has a smaller number of pixels has been shown, the invention is not so limited. The imaging element B may have a smaller number of pixels and may be driven.

(2) The numbers of pixels of the imaging elements are not limited to the numbers shown in the above description, and the imaging elements having other numbers of pixels may be used.

(3) While in the above description, the imaging element having 160 pixels horizontally and 120 pixels vertically has been used for producing a thumbnail, an imaging element by which 120 vertical pixels can be obtained as a result of driving the element for monitoring may be used and the horizontal pixels thereof may be skipped or interpolated so that it has 160 horizontal pixels.

According to the invention, first and second image data needed to produce an image file can be obtained based on image signals from the first and second imaging elements respectively and as such, the first and second image data, which have been sequentially produced based on a single kind of image signals in the past, can be produced substantially at a time. Therefore, the invention has the advantage that an image file including first and second image data can be produced at a higher speed. The invention is useful for an image processing apparatus having imaging elements such as CCDs (Charge Coupled Devices) and CMOSs (Complementary Metal Oxide Semiconductor) or the like.

1. An image processing apparatus for producing an image file including first and second image data, comprising:
a first imaging element and a second imaging element, converting light from an object into image signals; and
an image-converting section, converting image signals from said first and second imaging elements into the first and second image data respectively.

2. The image processing apparatus of claim 1, wherein said first imaging element is smaller than said second imaging element in pixel number.

3. The image processing apparatus of claim 1 or 2, further comprising:
an encoding device, combining the second image data encoded with a compression rate based on a code quantity of the first image data and the encoded first image data thereby to produce the image file.

4. The image processing apparatus of claim 3, wherein said encoding device makes the first and second image data fixed in length.

5. The image processing apparatus of claim 3 or 4, wherein said encoding device combines the encoded first image data as a thumbnail with the encoded second image data.
